(19) United States
(12) Patent Application Publication
(10) Pub. No.: US 2026/0036376 A1
(43) Pub. Date: Feb. 5, 2026

(54) PULSATING HEAT PIPE WITH WETTABILITY GRADIENT TO PROVIDE UNIDIRECTIONAL FLOW

(71) Applicant: Hamilton Sundstrand Corporation, Charlotte, NC (US)

(72) Inventors: Viktor Kilchyk, Williamsville, NY (US); Dmytro M. Voytovych, Rocky Hill, CT (US)

(21) Appl. No.: 18/792,162

(22) Filed: Aug. 1, 2024

(51) Int. Cl. F28D 15/02; B33Y 80/00; F28D 15/06

(52) U.S. Cl. CPC F28D 15/0266; F28D 15/0283; F28D 15/06; B33Y 80/00

(57) ABSTRACT

An oscillating heat pipe, having: a top region that connects with a heat sink; a bottom region that connects with a heat source; and an intermediate region extending between the top and bottom regions; wherein: the heat pipe is formed of a plurality of pipe segments connected, one after another, to define a closed loop; the plurality of pipe segments include a first segment; and the first segment includes a first portion, wherein the first portion is formed or treated to define a predetermined wettability gradient such that a flow through the first portion is unidirectional.

### BACKGROUND

The embodiments are directed to heat pipes for cooling systems in aircrafts, CPU/GPU/laser diodes, microchips, board-level cooling in servers, computers, radio frequency modules, energy storage or battery packs, avionics heat frames, motor stators/windings, thermal-mechanical structures (stators/vanes) embedded with oscillating heat pipes (OHP) and more specifically to a pulsating heat pipe with a wettability gradient to provide a unidirectional flow.

A pulsating heat pipe system often uses check valves, such as mechanical valves, to promote unidirectional circulation, thereby improving the thermal resistance of the system, preventing backflow, and stabilizing operation of the system. The mechanical valves, however, may add a structural complexity, size and a point of failure.

### BRIEF SUMMARY

Disclosed is an oscillating heat pipe, including: a top region that connects with a heat sink; a bottom region that connects with a heat source; and an intermediate region extending between the top and bottom regions; wherein: the heat pipe is formed of a plurality of pipe segments connected, one after another, to define a closed loop; the plurality of pipe segments include a first segment; and the first segment includes a first portion, wherein the first portion is formed or treated to define a predetermined wettability gradient such that a flow through the first portion is unidirectional to push flow from a heat source to a heat sink.

In addition to one or more aspects of the heat pipe or as an alternate, the predetermined wettability gradient is provided by one or more of: the first portion formed to define a predetermined flow geometry; the first portion coated with a predetermined surface coating; the first portion formed with a predetermined surface roughness; the first portion formed with a predetermined material gradient; or the first portion formed of a predetermined thermally responsive material that changes a wetting characteristic based on a flow temperature.

In addition to one or more aspects of the heat pipe or as an alternate, the heat pipe is additively manufactured.

In addition to one or more aspects of the heat pipe or as an alternate, the plurality of pipe segments include: a first vertical pipe segment extending between a first top end in the top region and a first bottom end in the bottom region; a second vertical pipe segment extending between a second top end in the top region and a second bottom end in the bottom region; a horizontal pipe segment extending in the top region between the first and second top ends; and an inner pipe segment extending along a serpentine path between the first and second bottom ends, and between the top and bottom regions.

In addition to one or more aspects of the heat pipe or as an alternate,: the inner pipe segment defines a plurality of inner segment peaks and inner segment troughs; and each of the inner segment peaks is located in the top region and each of the inner segment troughs is located in the bottom region.

In addition to one or more aspects of the heat pipe or as an alternate,: the first and second vertical pipe segments and the horizontal pipe segment define a U-shaped outer segment; and the inner pipe segment defines a plurality of U-shaped inner segments connected, one after another, between the first and second bottom ends, by respective horizontal trough segments, such that each of the U-shaped inner segments includes one of the inner segment peaks.

In addition to one or more aspects of the heat pipe or as an alternate,: each of the inner segment peaks is vertically level with each other and vertically offset from the horizontal pipe segment; and each of the inner segment troughs is level with each other and with the first and second bottom ends.

In addition to one or more aspects of the heat pipe or as an alternate, the heat pipe includes a check valve disposed in the intermediate region in one of the first and second vertical pipe segments.

In addition to one or more aspects of the heat pipe or as an alternate, the heat pipe includes: a charging tube connected to the horizontal pipe segment.

Further disclosed is a cooling system, including: a heat source; a heat sink located above the heat source; and an oscillating heat pipe, the heat pipe defines a top region, a bottom region and an intermediate region; and wherein the top region is coupled to the heat sink and the bottom region is coupled to the heat source, and the heat pipe is formed of a plurality of pipe segments connected, one after another, to define a closed loop; and wherein: the plurality of pipe segments include a first segment; and the first segment includes a first portion; and the first portion is formed or treated to define a predetermined wettability gradient such that a flow through the first portion is unidirectional to push flow from a heat source to a heat sink.

In addition to one or more aspects of the system or as an alternate, the predetermined wettability gradient is provided by one or more of: the first portion formed to define a predetermined flow geometry; the first portion coated with a predetermined surface coating; the first portion formed with a predetermined surface roughness; the first portion formed with a predetermined material gradient; or the first portion formed of a predetermined thermally responsive material that changes a wetting characteristic based on a flow temperature.

In addition to one or more aspects of the system or as an alternate, the heat pipe is additively manufactured.

In addition to one or more aspects of the system or as an alternate, the plurality of pipe segments include: a first vertical pipe segment extending between a first top end in the top region and a first bottom end in the bottom region; a second vertical pipe segment extending between a second top end in the top region and a second bottom end in the bottom region; a horizontal pipe segment extending in the top region between the first and second top ends; and an inner pipe segment extending along a serpentine path between the first and second bottom ends, and between the top and bottom regions.

In addition to one or more aspects of the system or as an alternate, the inner pipe segment defines a plurality of inner segment peaks and inner segment troughs; and each of the inner segment peaks is located in the top region and each of the inner segment troughs is located in the bottom region.

In addition to one or more aspects of the system or as an alternate: the first and second vertical pipe segments and the horizontal pipe segment define a U-shaped outer segment; and the inner pipe segment defines a plurality of U-shaped inner segments connected, one after another, between the first and second bottom ends, by respective horizontal trough segments, such that each of the U-shaped inner segments includes one of the inner segment peaks.

In addition to one or more aspects of the system or as an alternate: each of the inner segment peaks is vertically level with each other and vertically offset from the horizontal pipe segment; and each of the inner segment troughs is level with each other and with the first and second bottom ends.

In addition to one or more aspects of the system or as an alternate, the system includes a check valve disposed in the intermediate region in one of the first and second vertical pipe segments.

In addition to one or more aspects of the system or as an alternate, the system includes: a charging tube connected to the horizontal pipe segment.

### BRIEF DESCRIPTION OF THE DRAWINGS

The following descriptions should not be considered limiting in any way. With reference to the accompanying drawings, like elements are numbered alike:

FIG. 1 shows an aircraft that may utilize aspects of the disclosed embodiments;

FIG. 2 shows a pulsating heat pipe configured for a unidirectional flow according to the embodiments;

FIG. 3 shows a portion of the heat pipe showing a surface geometry on one circumferential side and a surface roughness on another circumferential side that provide a wettability gradient resulting in the unidirectional flow according to the embodiments;

FIG. 4 shows the portion of the heat pipe showing a surface coating on one circumferential side and a material gradient on another circumferential side that provide a wettability gradient resulting in the unidirectional flow according to the embodiments;

FIG. 5 is one implementation of the disclosed heat pipe; and

FIG. 6 is another implementation of the disclosed heat pipe.

### DETAILED DESCRIPTION

Aspects of the disclosed embodiments will now be addressed with reference to the figures. Aspects in any one figure are equally applicable to any other figure unless otherwise indicated. Aspects illustrated in the figures are for the purpose of supporting the disclosure and are not in any way intended to limit the scope of the disclosed embodiments. Any sequence of numbering in the figures is for reference purposes only.

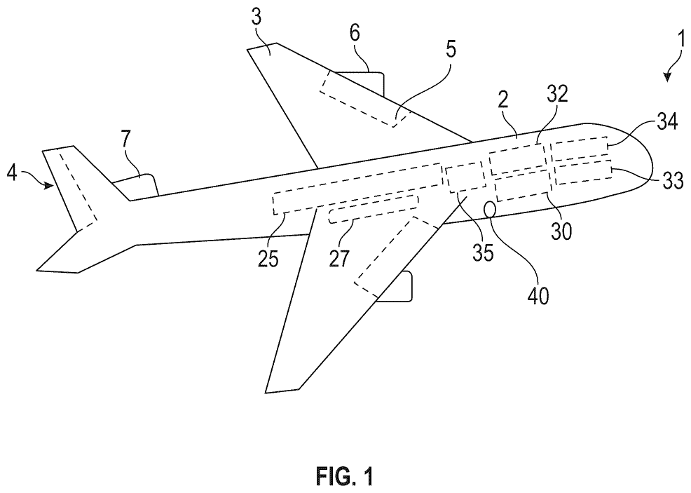

FIG. 1 shows an aircraft 1 having a fuselage 2 with a wing 3 and tail assembly 4, which may have control surfaces 5. The wing 3 may include an engine 6, such as a gas turbine engine, and an auxiliary power unit 7 may be disposed at the tail assembly 4. The aircraft 1 may have a cabin 25, a cargo bay 27, an environmental control system (ECS) 30 for conditioning the cabin 25 and/or cargo bay 27. The ECS 30 may include a vapor compression system (VCS) 32 that cools air directed to, e.g., the cargo bay 27 and provides refrigeration to one or more systems 35 of the aircraft 1, and an air cycle machine (ACM) 33 that cools air directed to e.g., the cabin 25. A RAM air inlet 40 may scoop air for the ECS 30, or the ECS 30 may receive air recirculated from, e.g., a cabin air compressor (CAC) 34.

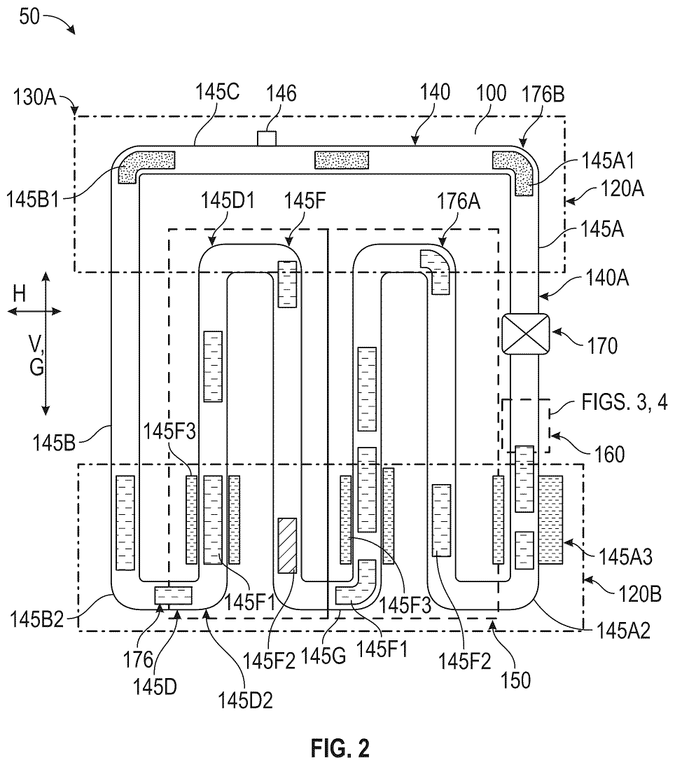

Turning to FIG. 2, a cooling system 50 is shown which may be utilized in one or more of the identified aircraft systems 35 such as electronics or motor cooling, or other aircraft systems. The cooling system 50 includes an oscillating heat pipe 100 (or for simplicity, a heat pipe 100) partially filled with a working fluid 176 (or flow). The heat pipe 100 includes a top region 120A that connects with a heat sink 130A to define a condensing region. A bottom region 120B of the heat pipe 100 connects with a heat source 130B to define an evaporating region. An intermediate region 120C of the heat pipe 100 extends between the top and bottom regions 120A, 120B. According to the embodiments, the heat pipe 100 is formed of a plurality of pipe segments 140 connected, one after another, to define a closed loop 150.

The top and bottom regions also can have fins on the outside for operating with gas agents. Also in the bottom region, pipes can be attached to heat sink surfaces like CPU/GPU or can be embedded into structure like vanes or stators.

The heat pipe 100 is a compact heat transfer device. The closed loop 150 is formed of a closed capillary tube or pipe folded into an oscillating or meandering shape. As heat is applied to the evaporator region 120B, the flow 176 in that section vaporizes, creating vapor bubbles 176A. Vapor in the condenser region 120A condenses back into liquid slugs 176B. A volume change in the flow 176 due to vaporization and condensation causes an oscillating motion of the liquid slugs 176B and vapor bubbles 176A within the loop 150. The liquid slugs 176B move back and forth between the hot and cold regions, facilitating a convective heat exchange. As the diameter of a loop 150 is relatively small, capillary action contributes in the flow and thermal dynamics. Heat input in the bottom region 120B results in either evaporation or boiling, increasing a pressure of the vapor bubbles 176A. Simultaneously, the pressure in the top region 120A decreases due to condensation. A resulting dynamic pressure variation drives the flow 176, i.e., the fluid motion, resulting in the heat transfer.

As shown in FIG. 2, the plurality of pipe segments 140 include, for example, a first segment 140A. The first segment 140A includes, for example, a first portion 160. According to the embodiments, the first portion 160 is formed or treated to define a predetermined wettability gradient 175. With the wettability gradient 175, the flow 176 along the first portion 160, and as a result, through the loop 150 is unidirectional to push flow from a heat source to a heat sink. It is to be appreciated that more than the first portion 160 of the first segment 140A may be formed or treated to define the predetermined wettability gradient 175. For example, entire segments or the entire loop 150, or other portions of the loop 150 may be formed or treated to define the predetermined wettability gradient 175.

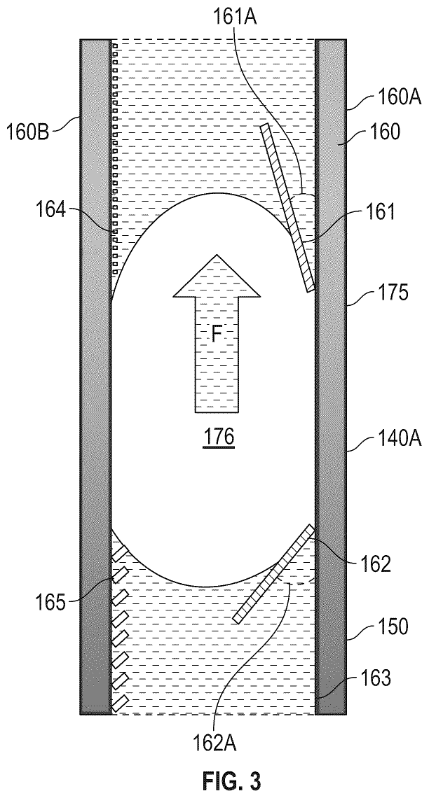

Turning to FIG. 3, as shown on a first circumferential side 160A of the first portion 160 (for simplicity) the predetermined wettability gradient 175 is provided by, for example, forming the first portion 160 to define a predetermined flow geometry. For example, the portion 160 is formed with upstream and downstream walls 161, 162 that induce wetting angles 161A, 162A that are different from each other. An aft one of the angles 162A is steeper (more acute) than a forward one of the angles 161A, to provide the wettability gradient 175 that results in unidirectional flow, i.e., in the forward direction F. That is, the wettability gradient 175 is shape-induced along the surface 163 of the first portion 160 to thereby induce desired wetting properties. It is to be appreciated that the walls 161, 162 of the pipe 100 may be formed as non-parallel wall segments, disposed at the different angles 161A and 162A, at a plurality of locations along the loop 150, to provide the desired unidirectional flow in the forward direction F. If the aft angle 162A is steeper than the forward angle 162A, as shown, along the direction of flow 176, the flow 176 may be urged to continue along the forward direction F. This may, in turn, urge the flow 176 along the forward direction F within the first segment 140A, and throughout the loop 150.

Also as shown in FIG. 3, as shown on a second circumferential side 160B of the first portion 160 (for simplicity), the predetermined wettability gradient 175 is provided by forming the first portion 160 with a predetermined surface roughness. The effect is similar to utilizing a predetermined surface geometry, discussed above. The roughness may be formed by forward and aft microstructures 164, 165 at patterns, angles and heights that differ from each other. This may effectively induce the wetting angles 161A, 162A that result in the desired unidirectional flow along in the forward direction F along the first portion 160 within the first segment 140A, and therefore throughout the loop 150.

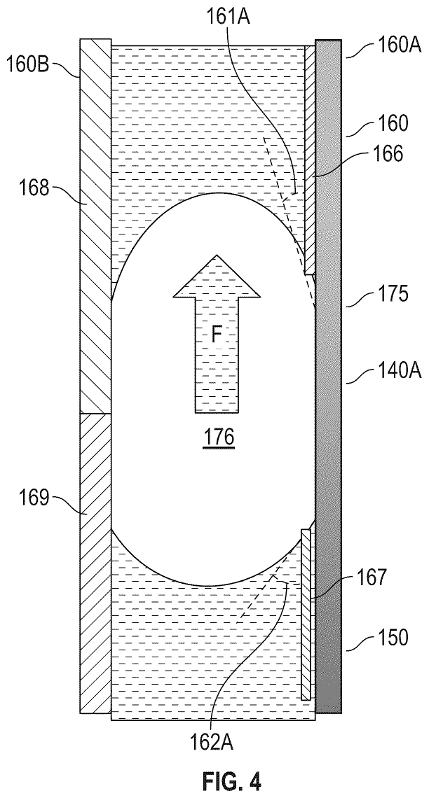

As shown in FIG. 4, as shown on the first circumferential side 160A of the first portion 160 (for simplicity), the predetermined wettability gradient 175 is provided by forming the first portion 160 with predetermined forward and aft surface coatings 166, 167. The coatings 166, 167 could provide a hydrophobic gradient that, similar to the surface geometry of FIG. 3, effectively induces the desired wetting angles 161A, 162A. The coatings 166, 167 may therefore result in the desired unidirectional flow that propels the flow 176 in the forward direction F along the first portion 160 within the first segment 140A, and therefore within the loop 150.

As also shown in FIG. 4, as shown on the second circumferential side 160B of the first portion 160 (for simplicity), the predetermined wettability gradient 175 is provided by forming the first portion 160 with a predetermined material gradient, i.e., transitioning from a first, forward material 168 to a second, aft material 169. Material differentials may provide a wettability gradient that effectively induces the desired wetting angles 161A, 162A. The different materials 168, 169 may therefore result in the desired unidirectional flow that propels the flow 176 in the forward direction along the forward direction along the first portion 160 within the first segment 140A, and therefore within the loop 150.

According to the embodiments, the materials 168, 169 may be thermally responsive to provide the desired wettability gradient 175. That is, responsive to temperature in the vapor bubbles 176A or liquid slugs 176B in the flow 176, a changing wettability gradient in the materials may effectively induce the desired wetting angles 161A, 162A. The different materials 168, 169 may therefore result in the desired unidirectional flow that propels the flow 176 in the forward direction F along the first portion 160 within the first segment 140A, and therefore within the loop 150. That is, thermally responsive materials 168, 169 may be utilized to change the wetting characteristics based on a flow temperature.

As indicated, for simplicity, the geometric configurations (FIG. 3), surface roughness (FIG. 3), coatings (FIG. 4), and material gradients (FIG. 4) are shown on different circumferential sides 160A, 160B of the portion 160 of the segment 140A of the heat pipe 100. It is to be appreciated that only one of these aspects may be utilized around the entire circumference of the inner surface 163 of the portion 160 of the segment 140A of the heat pipe 100 to obtain the desired wettability gradient 175. However, a combination of the different aspects shown in FIGS. 3 and 4 may be utilized along portions of the circumference or around the entire circumference of the portion 160 of the segment 140A of the heat pipe 100 to obtain the desired wettability gradients 175. As indicated, the application of the different aspects shown in FIGS. 3 and 4 may be applied throughout the loop 150 or in other portions of the loop 150 to obtain the desired unidirectional flow. In one embodiment, the heat pipe 100 is additively manufactured to obtain the one or more of the above aspects that provide the desired wettability gradient 175.

Turning back to FIG. 2, the plurality of pipe segments 140 include a first vertical pipe segment 145A extending along the vertical direction V, which in operation is parallel to the direction of gravity G. The first vertical pipe segment 145A extends between a first top end 145A1 in the top region 120A and a first bottom end 145A2 in the bottom region 120B. A second vertical pipe segment 145B extends between a second top end 145B1 in the top region 120A and a second bottom end 145B2 in the bottom region 120B. A horizontal pipe segment 145C extends along the horizontal direction H in the top region 120A between the first and second top ends 145A1, 145B1. A charging tube 146, for filling and refiling the loop 150, may be connected to the horizontal pipe segment 145C.

An inner pipe segment 145D extends along a serpentine or oscillating path. The inner pipe segment 145D extends between the first and second bottom ends 145A2, 145B2, and between the top and bottom regions 120A, 120B.

More specifically, the first and second vertical pipe segments 145A, 145B and the horizontal pipe segment 145C define a U-shaped outer segment 145E. The inner pipe segment 145D defines a plurality of inner segment peaks 145D1 and inner segment troughs 145D2. Each of the inner segment peaks 145D1 is located in the top region 120A. Each of the inner segment troughs 145D2 is located in the bottom region 120B.

As shown in FIG. 2, the inner pipe segment 145D defines a plurality of U-shaped inner segments 145F connected, one after another, between the first and second bottom ends 145A2, 145B2, by respective horizontal trough segments 145G. A number of U-shaped inner segments 145F that are utilized may depend on expected loading. Each of the U-shaped inner segments 145F has a pair vertical tubes (pipe segments) 145F1, 145F2 at least one of which 145F1 defines wettable surfaces (e.g., with a wettability coating) 145F3. Similarly at least one 145A of the outer vertical tubes 145A, 145B defines wettable surfaces (e.g., with a wettability coating) 145A3. Each of the U-shaped inner segments 145F includes one of the inner segment peaks 145D1. Each of the inner segment peaks 145D1 is vertically level with each other and vertically offset below the horizontal pipe segment 145C. Each of the inner segment troughs 145D2 is level with each other and with the first and second bottom ends 145A2, 145B2. The inner pipe segment 145D is horizontally between the outer vertical pipe segments 145A, 145B.

In one embodiment, a check valve 170 disposed in the intermediate region 120C in one of the first and second vertical pipe segments 145A, 145B, though it may be located elsewhere in the loop 150. Though in accordance with the embodiments, the check valve 170 is optional and not required to provide for unidirectional flow throughout the loop 150.

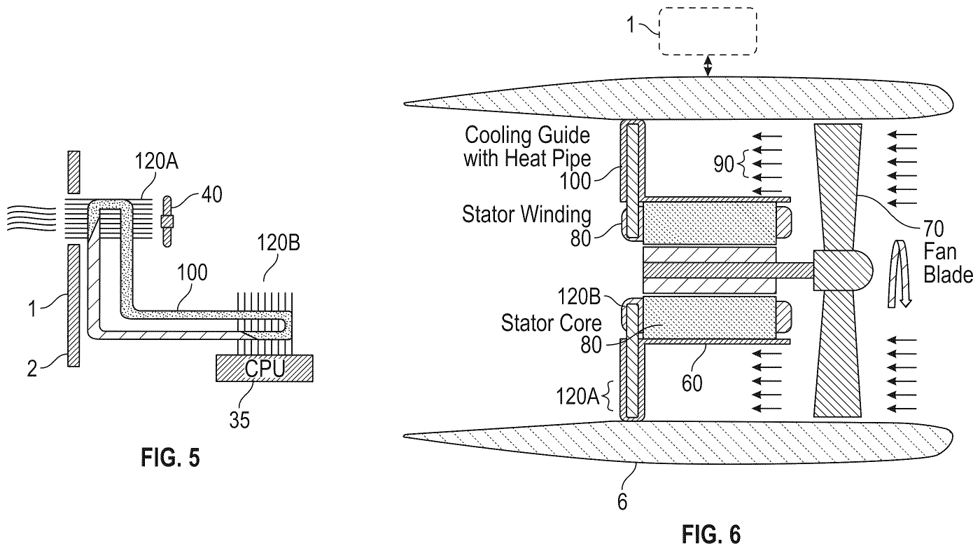

Turning to FIG. 5, the heat pipe 100 may be utilized to cool electronics 35 on an aircraft 1. The evaporator region (or section) 120B may be coupled to the electronics 35 and the condensing section 120A may be subject to cooling with ram air 40 and ejected out of the fuselage 2.

Turning to FIG. 6, engine 6 of the aircraft 1 may have a motor 60 driven fan 70 and the heat pipe 100 may be utilized to cool electronics 35 of the motor 60 including the stator winding 80. The evaporator region (or section) 120B may be coupled to the stator winding 80 and the condensing section 120A may be subject to cooling with air 90 from the fan 70.

Other systems 35 that may include the implementation of the heating pipe 100 include cooling CPU, GPU. laser diodes, microchips, board-level cooling in servers, computers, radio frequency modules, energy storage or battery packs, avionics heat frames, motor stators/windings, and thermal-mechanical structures (stators/vanes) embedded with OHP.

As indicated, pulsating heat pipes, such as the heat pipe 100, offer several advantages, including simplicity, compactness, and high heat transfer efficiency. Benefits of the embodiments include an increased mass transfer of the flow 176 and thus heat cooling capacity through the loop 150. With fewer moving parts there is a higher system reliability both at startup and throughout operation of the system 50, including during, e.g., translational acceleration. As indicated, additive manufacturing of the heat pipe 100 provides the ability to generate a variable surface wetting gradient. The gradient may be obtained utilizing one or more of the aspects shown in FIGS. 3 and 4, distributed about part of or an entity of a circumference of at least a portion 160 of a segment 140A of the heat pipe 100.

The terminology used herein is for the purpose of describing particular embodiments only and is not intended to be limiting of the present disclosure. The term “about” is intended to include the degree of error associated with measurement of the particular quantity and/or manufacturing tolerances based upon the equipment available at the time of filing the application. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

Those of skill in the art will appreciate that various example embodiments are shown and described herein, each having certain features in the particular embodiments, but the present disclosure is not thus limited. Rather, the present disclosure can be modified to incorporate any number of variations, alterations, substitutions, combinations, sub-combinations, or equivalent arrangements not heretofore described, but which are commensurate with the scope of the present disclosure. Additionally, while various embodiments of the present disclosure have been described, it is to be understood that aspects of the present disclosure may include only some of the described embodiments. Accordingly, the present disclosure is not to be seen as limited by the foregoing description, but is only limited by the scope of the appended claims.

What is claimed is:

1. An oscillating heat pipe, comprising:
a top region that connects with a heat sink;
a bottom region that connects with a heat source; and
an intermediate region extending between the top and bottom regions;
wherein:
the heat pipe is formed of a plurality of pipe segments connected, one after another, to define a closed loop;
the plurality of pipe segments include a first segment; and
the first segment includes a first portion,
wherein the first portion is formed or treated to define a predetermined wettability gradient such that a flow through the first portion is unidirectional to push flow from a heat source to a heat sink.

2. The heat pipe of claim 1, wherein the predetermined wettability gradient is provided by one or more of:
the first portion formed to define a predetermined flow geometry;
the first portion coated with a predetermined surface coating;
the first portion formed with a predetermined surface roughness;
the first portion formed with a predetermined material gradient; or
the first portion formed of a predetermined thermally responsive material that changes a wetting characteristic based on a flow temperature.

3. The heat pipe of claim 1, wherein the heat pipe is additively manufactured.

4. The heat pipe of claim 1, wherein the plurality of pipe segments include:
a first vertical pipe segment extending between a first top end in the top region and a first bottom end in the bottom region;
a second vertical pipe segment extending between a second top end in the top region and a second bottom end in the bottom region;
a horizontal pipe segment extending in the top region between the first and second top ends; and
an inner pipe segment extending along a serpentine path between the first and second bottom ends, and between the top and bottom regions.

5. The heat pipe of claim 4, wherein:
the inner pipe segment defines a plurality of inner segment peaks and inner segment troughs; and
each of the inner segment peaks is located in the top region and each of the inner segment troughs is located in the bottom region.

6. The heat pipe of claim 5, wherein:
the first and second vertical pipe segments and the horizontal pipe segment define a U-shaped outer segment; and
the inner pipe segment defines a plurality of U-shaped inner segments connected, one after another, between the first and second bottom ends, by respective horizontal trough segments, such that each of the U-shaped inner segments includes one of the inner segment peaks.

7. The heat pipe of claim 6, wherein:
each of the inner segment peaks is vertically level with each other and vertically offset from the horizontal pipe segment; and
each of the inner segment troughs is level with each other and with the first and second bottom ends.

8. The heat pipe of claim 1, further comprising a check valve disposed in the intermediate region in one of the first and second vertical pipe segments.

9. The heat pipe of claim 4, further comprising:
a charging tube connected to the horizontal pipe segment.

10. A cooling system, comprising:
a heat source;
a heat sink located above the heat source; and
an oscillating heat pipe, the heat pipe defines a top region, a bottom region and an intermediate region; and
wherein the top region is coupled to the heat sink and the bottom region is coupled to the heat source, and
the heat pipe is formed of a plurality of pipe segments connected, one after another, to define a closed loop; and
wherein:
the plurality of pipe segments include a first segment; and
the first segment includes a first portion; and
the first portion is formed or treated to define a predetermined wettability gradient such that a flow through the first portion is unidirectional to push flow from a heat source to a heat sink.

11. The system of claim 10, wherein the predetermined wettability gradient is provided by one or more of:
the first portion formed to define a predetermined flow geometry;
the first portion coated with a predetermined surface coating;
the first portion formed with a predetermined surface roughness;
the first portion formed with a predetermined material gradient; or
the first portion formed of a predetermined thermally responsive material that changes a wetting characteristic based on a flow temperature.

12. The system of claim 10, wherein the heat pipe is additively manufactured.

13. The system of claim 10, wherein the plurality of pipe segments include:
a first vertical pipe segment extending between a first top end in the top region and a first bottom end in the bottom region;
a second vertical pipe segment extending between a second top end in the top region and a second bottom end in the bottom region;
a horizontal pipe segment extending in the top region between the first and second top ends; and
an inner pipe segment extending along a serpentine path between the first and second bottom ends, and between the top and bottom regions.

14. The system of claim 13, wherein:
the inner pipe segment defines a plurality of inner segment peaks and inner segment troughs; and
each of the inner segment peaks is located in the top region and each of the inner segment troughs is located in the bottom region.

15. The system of claim 14, wherein:
the first and second vertical pipe segments and the horizontal pipe segment define a U-shaped outer segment; and
the inner pipe segment defines a plurality of U-shaped inner segments connected, one after another, between the first and second bottom ends, by respective horizontal trough segments, such that each of the U-shaped inner segments includes one of the inner segment peaks.

16. The system of claim 15, wherein:
each of the inner segment peaks is vertically level with each other and vertically offset from the horizontal pipe segment; and
each of the inner segment troughs is level with each other and with the first and second bottom ends.

17. The system of claim 10, further comprising a check valve disposed in the intermediate region in one of the first and second vertical pipe segments.

18. The system of claim 13, further comprising:
a charging tube connected to the horizontal pipe segment.
